(19) United States
(12) Patent Application Publication
(10) Pub. No.: US 2013/0256786 A1
(43) Pub. Date: Oct. 3, 2013

(54) TRENCH MOSFET WITH SHIELDED ELECTRODE AND AVALANCHE ENHANCEMENT REGION

(71) Applicant: Fu-Yuan HSIEH, New Taipei City (TW)

(72) Inventor: Fu-Yuan HSIEH, New Taipei City (TW)

(73) Assignee: FEEI CHERNG ENTERPRISE CO., LTD., New Taipei City (TW)

(21) Appl. No.: 13/433,627

(22) Filed: Mar. 29, 2012

(51) Int. Cl. H01L 29/78; H01L 21/336

(52) U.S. Cl. 257/330; 438/270; 257/E29.262; 257/E21.41

(57) ABSTRACT

A trench MOSFET with shielded electrode and improved avalanche enhancement region is disclosed. The inventive structure can achieve a better avalanche capability by applying an improved avalanche enhancement region having a same doping concentration as the epitaxial layer where said trench MOSFET is formed without increasing Rds.

### FIELD OF THE INVENTION

This invention relates generally to the cell structure, device configuration and fabrication process of power semiconductor devices. More particularly, this invention relates to a novel and improved cell structure, device configuration and improved fabrication process of a trench MOSFET (Metal Oxide Semiconductor Field Effect Transistor) with shielded electrode and avalanche enhancement region.

### BACKGROUND OF THE INVENTION

Prior art U.S. Pat. No. 7,091,573 disclosed a trench metal oxide semiconductor field effect transistor (hereinafter MOSFET) 100 (as shown in FIG. 1A) with a shielded electrode 101 in a trenched gate, which has reduced Rds (resistance between drain and source) and Qgd (charge between gate and drain) compared to a conventional trench MOSFET having a single electrode in a trenched gate, making an excellent choice for power switching applications such as inverter and DC to DC power supply circuits. However, the trench MOSFET 100 as shown in FIG. 1A still encounters a technical problem which is that, avalanche always occurs along a channel region at an interface between a gate oxide 102 close to a gate electrode 103 and a field oxide 104 close to the shielded electrode 105, as illustrated in FIG. 1A. This is because the field oxide is usually thicker than the gate oxide, resulting in significant increase in electric field at the interface.

To improve the avalanche capability, another Prior art U.S. Patent Pub. No.: 2010/0320532 disclosed a trench MOSFET with shielded electrode and an additional p− region (in an N-channel trench MOSFET) extending from body region towards a trench bottom, as shown in FIG. 1B and FIG. 1C. In FIG. 1B, the N-channel trench MOSFET 110 has a p− region 111 extending from a p body region 112 to a depth 113 which is below a shielded region 114. In FIG. 1C, the N-channel trench MOSFET 120 has a p− region 121 extending from a p body region 122 to a depth 123 which is at a top of a shielded region 124. Compared to the trench MOSFET 100 in FIG. 1A, the two of the N-channel trench MOSFET 110 and 120 both have improved avalanche capability due to the introduction of the p− region 111 and 121, however, they also have significantly increased Rds because of channel length increase.

Therefore, there is still a need in the art of the semiconductor power device, particularly for a trench MOSFET with shielded electrode design and fabrication, to provide a novel cell structure, device configuration and fabrication process that would resolve these difficulties and design limitations.

### SUMMARY OF THE INVENTION

The present invention provides a trench MOSFET with shielded electrode and avalanche enhancement region to improve the avalanche capability without significantly increasing Rds. In one aspect, the present invention features a trench MOSFET comprising: a substrate of a first conductivity type; an epitaxial layer of the first conductivity type onto the substrate, the epitaxial layer having a lower doping concentration than the substrate; a plurality of active trenches formed in the epitaxial layer in an active area, each comprising a shielded electrode (illustrated as S for example in FIG. 2C) in a lower portion and a gate electrode (illustrated as G for example in FIG. 2C) in an upper portion, wherein the shielded electrode is insulated from the epitaxial layer by a field oxide and the gate electrode is insulated from source regions of said first conductivity type and body regions of a second conductivity type by a gate oxide which is usually thinner than the field oxide, wherein the shielded electrode and the gate electrode are insulated from each other by an inter-poly insulating layer; avalanche enhancement regions of the first conductivity type formed adjacent sidewalls of each of the active trenches below the body regions and towards a bottom of each of the active trenches, wherein the avalanche enhancement regions have a lower doping concentration than the epitaxial layer.

According to another aspect of the present invention, in some preferred embodiments, the avalanche enhancement regions further extends below the gate oxide but above a bottom of the shielded electrode. In some other preferred embodiments, the avalanche enhancement regions further extends surrounding the bottom of each of the active trenches.

According to another aspect of the present invention, the trench MOSFET further comprises a trenched source-body contact filled with a contact metal plug and penetrating through a contact interlayer overlying the epitaxial layer, and further extending through the source regions and into the body regions. More preferred, in some preferred embodiments, the source regions are formed by laterally and vertically diffused and having a greater junction depth and a higher doping concentration along sidewalls of the trenched source-body contact than along an adjacent channel region near the active trenches at a same distance from a top surface of the epitaxial layer. In some other preferred embodiments, the source regions are formed by vertically diffused and having a same junction depth and a same doping concentration from sidewalls of the trenched source-body contact to an adjacent channel region near the active trenches at a same distance from the top surface of the epitaxial layer.

According to another aspect of the present invention, in some preferred embodiments, the inter-poly insulating layer has a same thickness as the gate oxide. In some other preferred embodiments, the inter-poly insulating layer has a greater thickness than the gate oxide.

According to another aspect of the present invention, the contact metal plug is Al alloys or Ni/Ag padded by a barrier metal layer of Ti/TiN, which is further out extending to overly the contact interlayer to act as a source metal. In some preferred embodiments, the contact metal plug is tungsten plug padded by a barrier metal layer of Ti/TiN or Co/TiN or Ta/TiN, and is connected to a source metal. More preferred, the contact metal plug is also extending over a top surface of the contact interlayer.

According to another aspect of the present invention, in some preferred embodiments, the source metal is Al alloys or Ni/Ag padded by a resistance-reduction layer of Ti or Ti/TiN on top surface of the tungsten plug. In some other preferred embodiments, the source metal is Al alloys or Ni/Ag and not padded by a resistance-reduction layer.

According to another aspect of the present invention, the trench MOSFET further comprises a termination area comprising multiple trenched floating gates.

The invention also features a method of making a trench MOSFET with shielded electrode, comprising: forming a plurality of active trenches in an epitaxial layer of a first conductivity type supported onto a substrate of the first conductivity type; forming a shielded electrode padded by a field oxide in a lower portion of each of the active trenches; forming a gate oxide covering top surface of the shielded electrode and the field oxide and along an upper sidewalls of each of the active trenches; carrying out angle ion implantations to form avalanche enhancement regions of the first conductivity type in the epitaxial layer and along the upper sidewalls of each of the active trenches, wherein the avalanche enhancement regions have a lower doping concentration than the epitaxial layer. After forming the avalanche enhancement regions, the invention further features a method to making a inter-poly insulating layer having a greater thickness than the gate oxide, comprising: depositing an un-doped or doped poly-silicon layer overlying the gate oxide; depositing a nitride layer overlying the un-doped or doped poly-silicon layer; carrying out anisotropic nitride etch to form nitride sidewalls spacers along the upper sidewalls of each of the active trenches; performing thermal oxidation to form a thick oxide on top surface of the shielded electrode, to form an inter-poly insulating layer including the thick oxide and the gate oxide on top of the shielded electrode which has a greater thickness than said gate oxide.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1A is a cross-sectional view of a trench MOSFET with shielded electrode of prior art.

FIG. 1B is a cross-sectional view of another trench MOSFET with shielded electrode of prior art.

FIG. 1C is a cross-sectional view of another trench MOSFET with shielded electrode of prior art.

FIG. 2A is a cross-sectional view of a preferred embodiment according to the present invention.

FIG. 2B is a cross-sectional view of another preferred embodiment according to the present invention.

FIG. 2C is a cross-sectional view of another preferred embodiment according to the present invention.

FIG. 3A is a cross-sectional view of another preferred embodiment according to the present invention.

FIG. 3B is a cross-sectional view of another preferred embodiment according to the present invention.

FIG. 3C is a cross-sectional view of another preferred embodiment according to the present invention.

FIG. 4 is a cross-sectional view of another preferred embodiment according to the present invention.

FIG. 5 is a cross-sectional view of another preferred embodiment according to the present invention.

FIGS. 6A-6K are a serial of side cross-sectional views for showing the processing steps for fabricating the super-junction trench MOSFET as shown in FIG. 5.

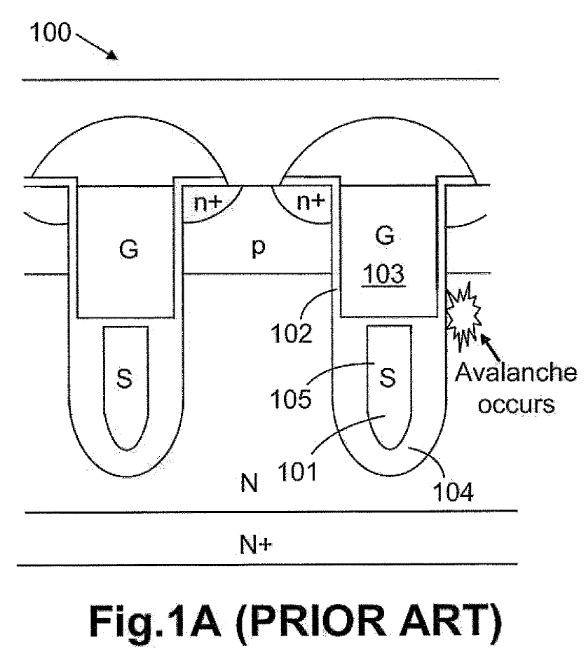

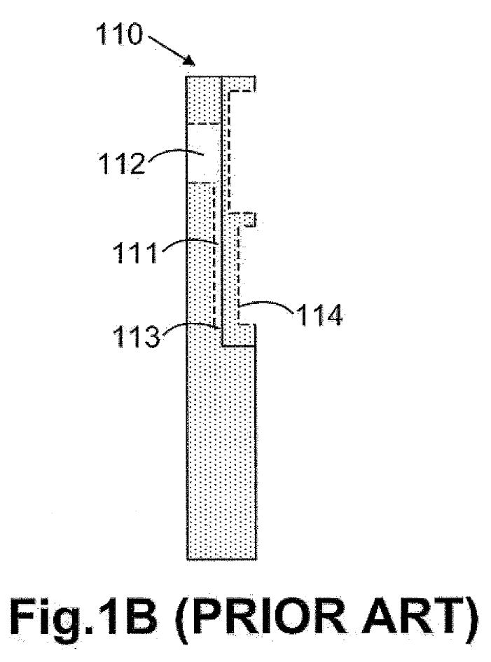

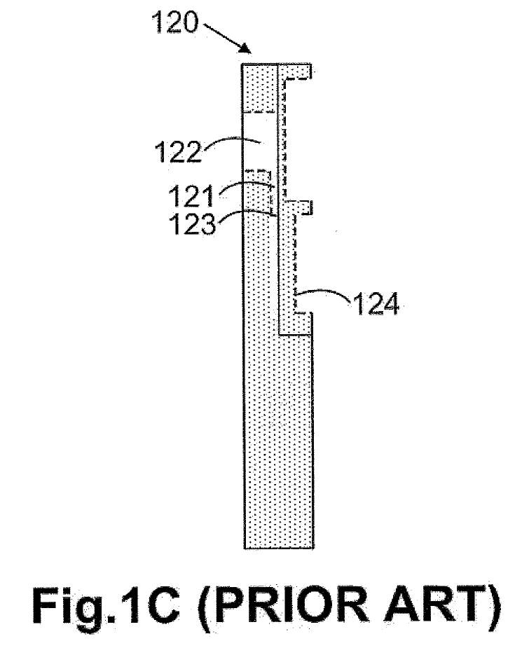

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be make without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

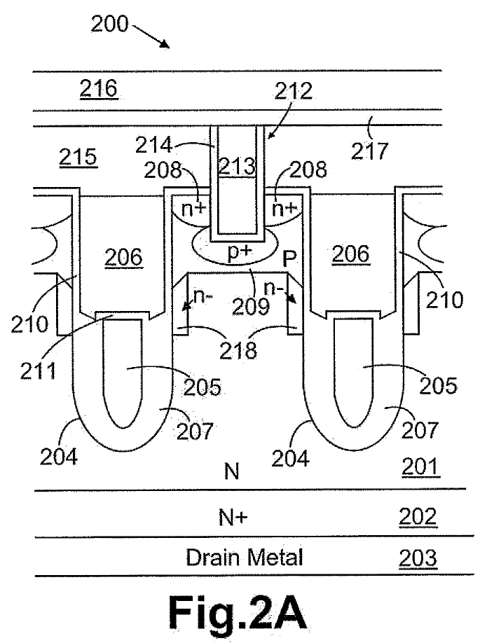

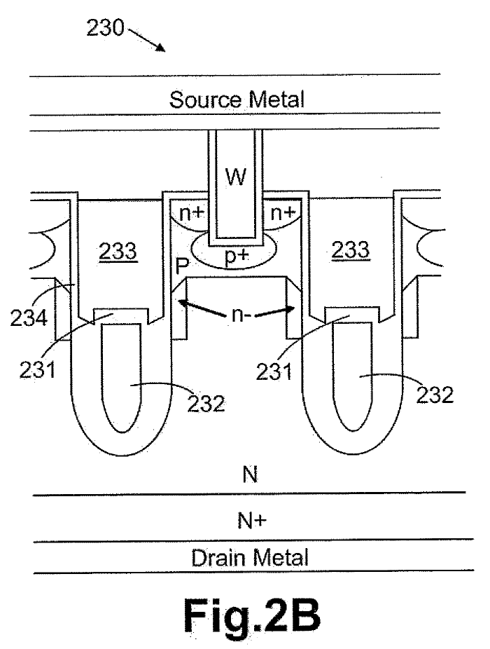

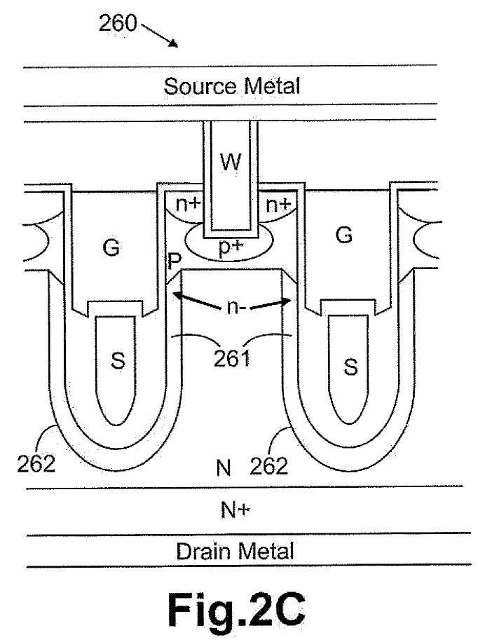

Please refer to FIG. 2A for a preferred embodiment of this invention where an N-channel trench MOSFET 200 is formed in an N epitaxial layer 201 onto an N+ substrate 202 coated with a back metal on a rear side as a drain metal 203. A plurality of active trenches 204 are formed starting from an upper surface of the N epitaxial layer 201 and vertically down in an active area. Each of the active trenches 204 comprises a shielded electrode 205 of p type or n type in a lower portion and a gate electrode 206 of n+ type in an upper portion, wherein the shielded electrode 205 is insulated from the N epitaxial layer 201 by a field oxide 207, the gate electrode 206 is insulated from an n+ source region 208 and a P body region 209 by a gate oxide 210, wherein the field oxide 207 has a greater thickness than the gate oxide 210. Furthermore, the shielded electrode 205 is insulated from the gate electrode 206 by an inter-poly insulating layer 211 which has a same thickness as the gate oxide 210 in this embodiment. Specifically, the n+ source region 208 is formed by laterally diffused, and each has a greater junction depth and a higher doping concentration along sidewalls of a trenched source-body contact 212 than along an adjacent channel region near the active trenches 204 at a same distance from a top surface of the N epitaxial layer 201, wherein the trenched source-body contact 212 is filled with a tungsten plug 213 padded by a barrier layer 214 of Ti/TiN or Co/TiN or Ta/TiN while penetrating through a contact interlayer 215, the n+ source region 208 and extending into the P body region 209, connecting the n+source region 208 and the P body region 209 to a source metal 216 of Al alloys or Ni/Ag which is padded by a resistance-reduction layer 217 of Ti or Ti/TiN.

The most important is that, the N-channel trench MOSFET 200 further comprises n− avalanche enhancement regions 218 along sidewalls of each of the active trenches 204 below the P body region 209 and above bottom of the shielded electrode 205 to improve the avalanche capability without increasing Rds, wherein the n− avalanche enhancement regions 218 have a lower doping concentration than the N epitaxial layer 201.

Please refer to FIG. 2B for another N-channel trench MOSFET 230 according to the present invention, which is similar to the N-channel trench MOSFET 200 in FIG. 2A except that, the inter-poly insulating layer 231 between the shielded electrode 232 and the gate electrode 233 has a greater thickness than the gate oxide 234 close to sidewalls of the gate electrode 233 to sustain a higher voltage between the gate electrode 233 and the shielded electrode 232.

Please refer to FIG. 2C for another N-channel trench MOSFET 260 according to the present invention, which is similar to the N-channel trench MOSFET 200 in FIG. 2A except that, the n− avalanche enhancement regions 261 further extend to surround bottom of each of the active trenches 262.

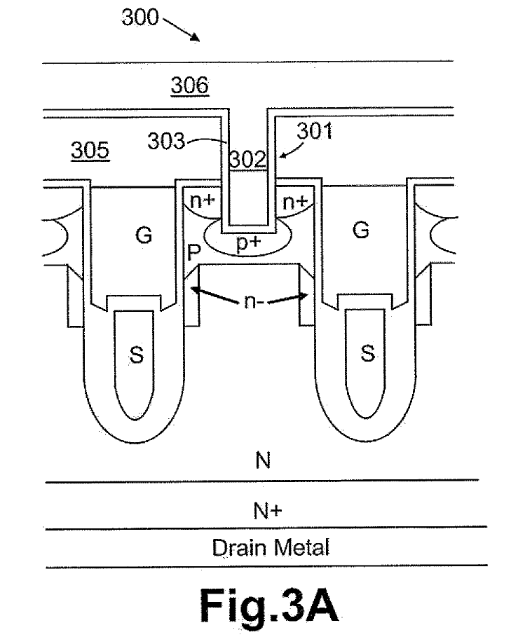

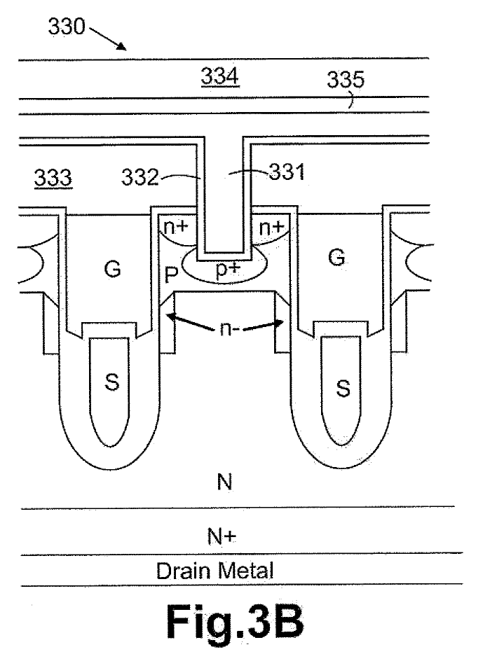

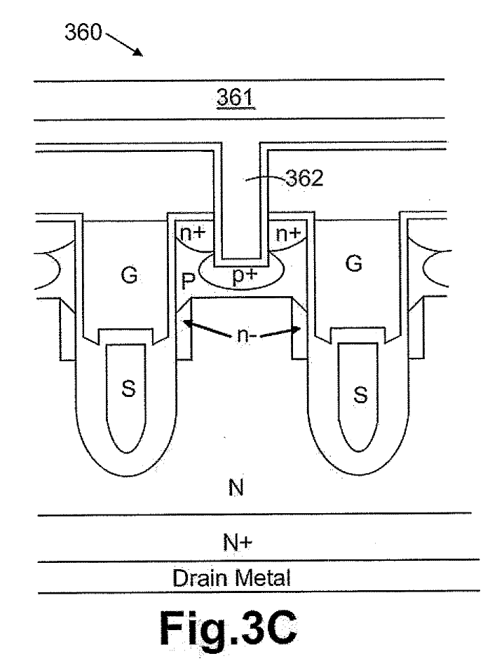

Please refer to FIG. 3A for another N-channel trench MOSFET 300 according to the present invention, which is similar to the N-channel trench MOSFET 230 in FIG. 2B except that, the trenched source-body contact 301 is filled with Al alloys plug or Ni/Ag plug 302 padded by a barrier metal layer 303 of Ti/TiN to serve as a contact metal plug which is further out extending to cover a top surface of the contact interlayer 305 to serve as the source metal 306.

Please refer to FIG. 3B for another N-channel trench MOSFET 330 according to the present invention, which is similar to the N-channel trench MOSFET 230 in FIG. 2B except that, the tungsten plug 331 padded by the barrier layer 332 of Ti/TiN or Co/TiN or Ta/TiN is also extending over a top surface of the contact interlayer 333 and underneath the source metal 334 padded by the resistance-reduction layer 335 of Ti or Ti/TiN.

Please refer to FIG. 3C for another N-channel trench MOSFET 360 according to the present invention, which is similar to the N-channel trench MOSFET 330 in FIG. 3B except that, the source metal 361 overlying the tungsten plug 362 is not padded by a resistance-reduction layer, that is to say, there is no Ti or Ti/TiN layer disposed between the source metal 361 and the tungsten layer.

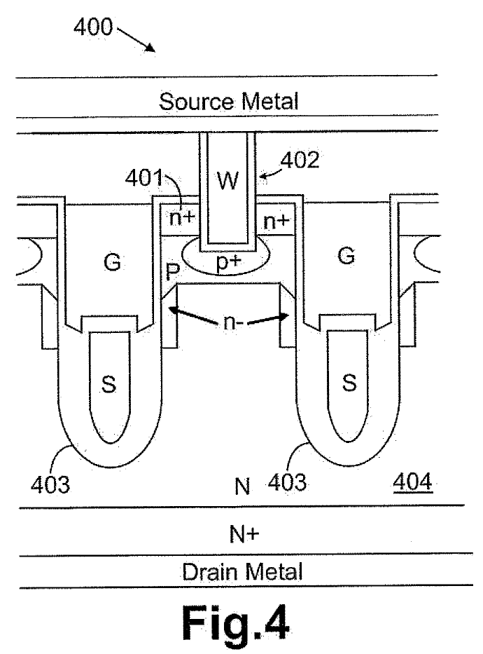

Please refer to FIG. 4 for another N-channel trench MOSFET 400 according to the present invention, which is similar to the N-channel trench MOSFET 230 in FIG. 2B except that, the n+ source region 401 is formed by vertical diffusion, therefore has a same junction depth and a same doping concentration from sidewalls of the trenched source-body contact 402 to an adjacent channel region near the active trenches 403 at a same distance from a top surface of the N epitaxial layer 404.

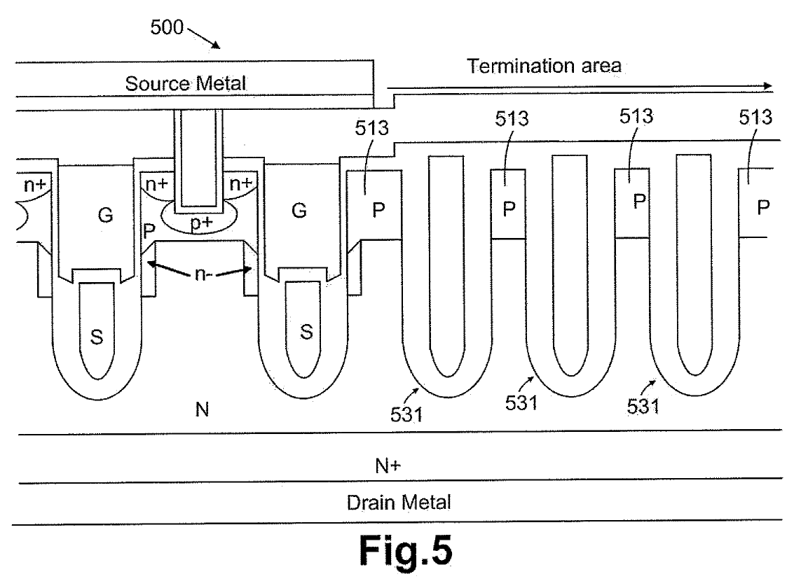

Please refer to FIG. 5 for another N-channel trench MOSFET 500 according to the present invention, which is similar to the N-channel trench MOSFET 230 in FIG. 2B except that, the N-channel trench MOSFET 500 further have a termination area comprising multiple trenched floating gates 531 spaced apart by a plurality of P body regions 513.

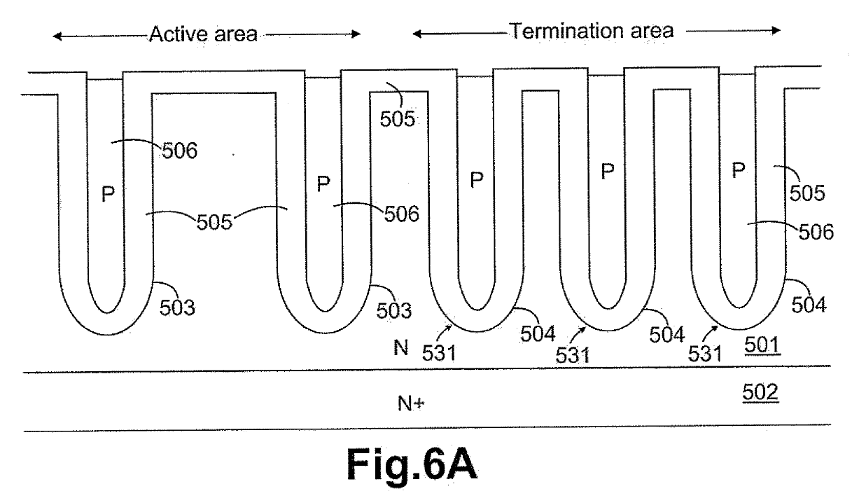

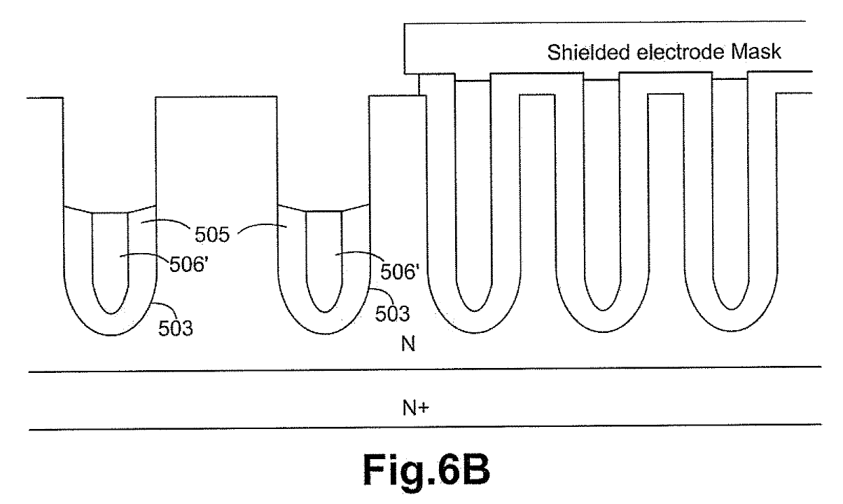

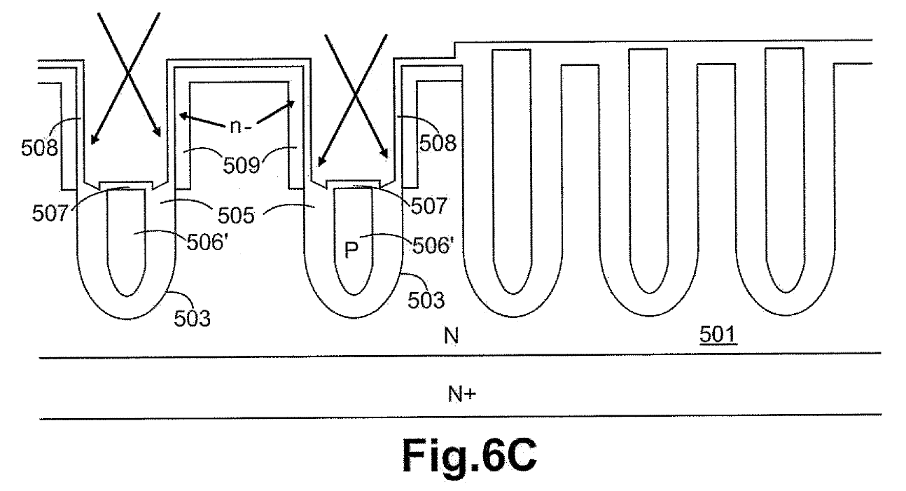

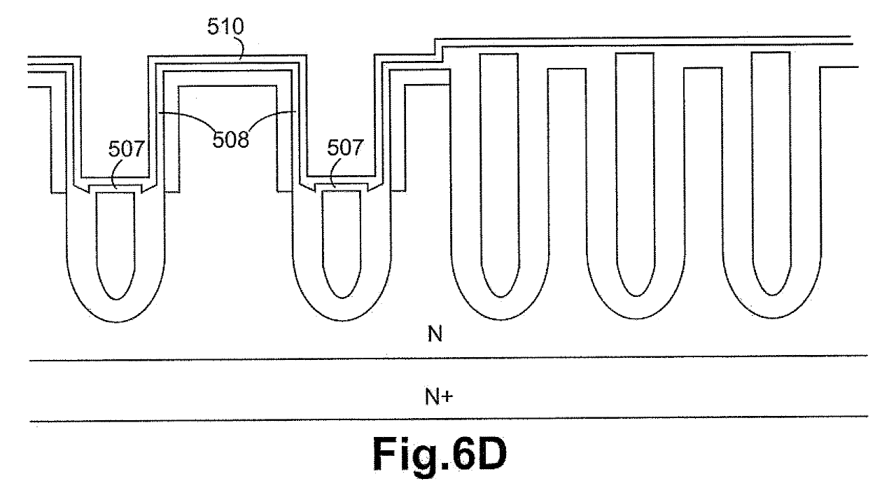

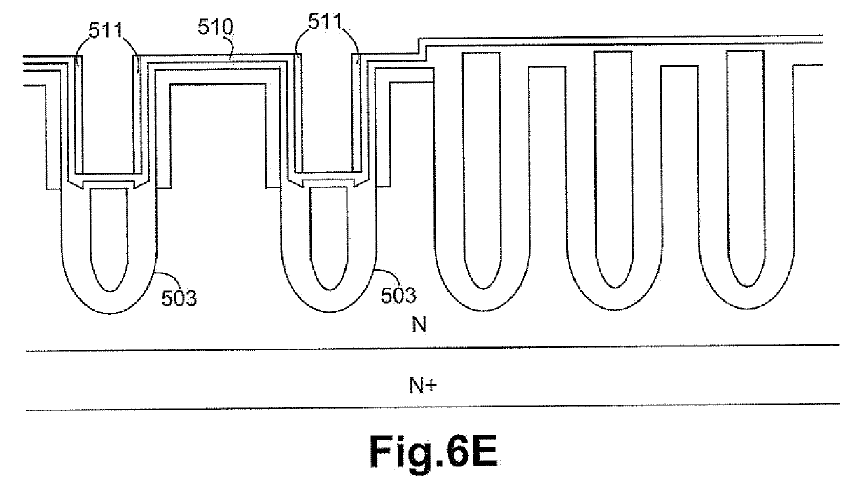

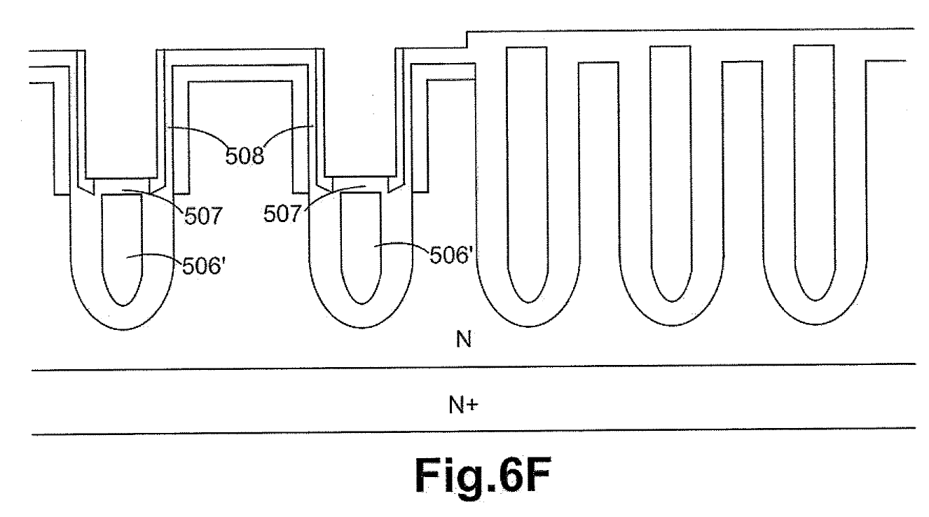

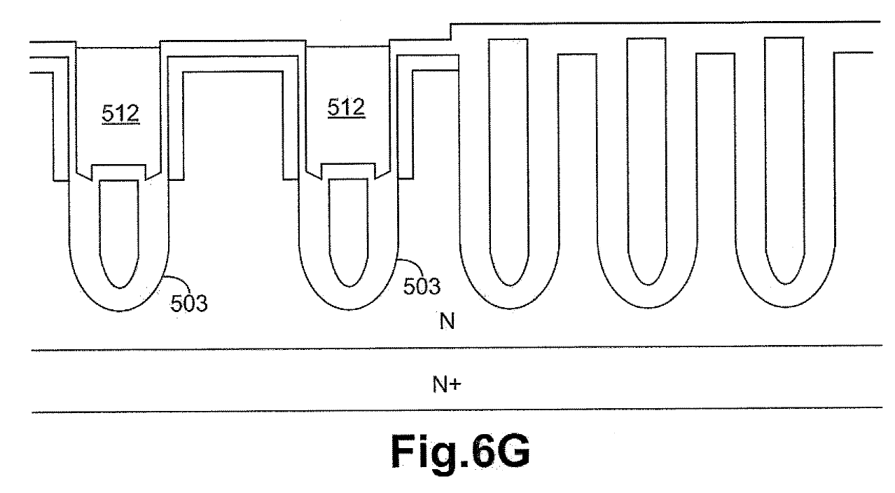

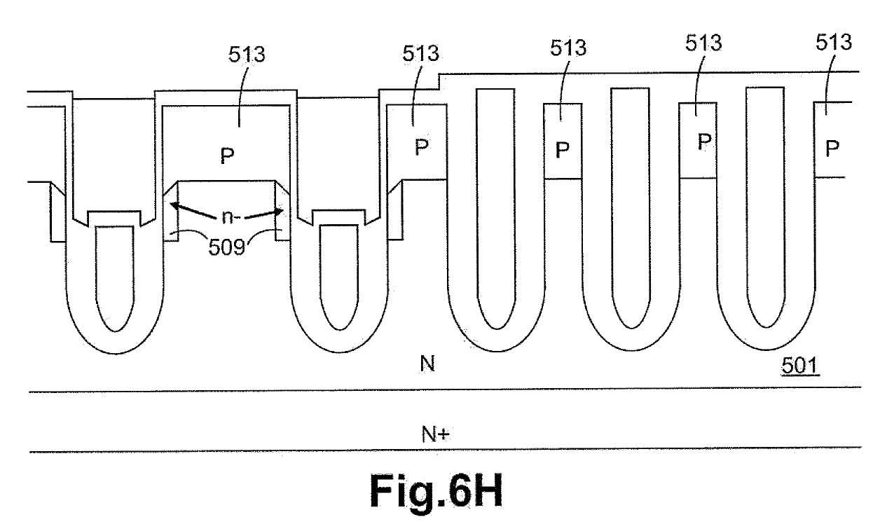

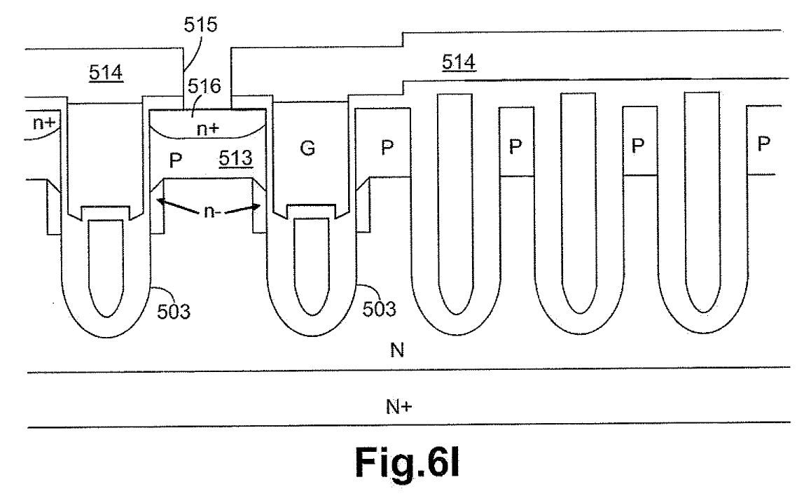

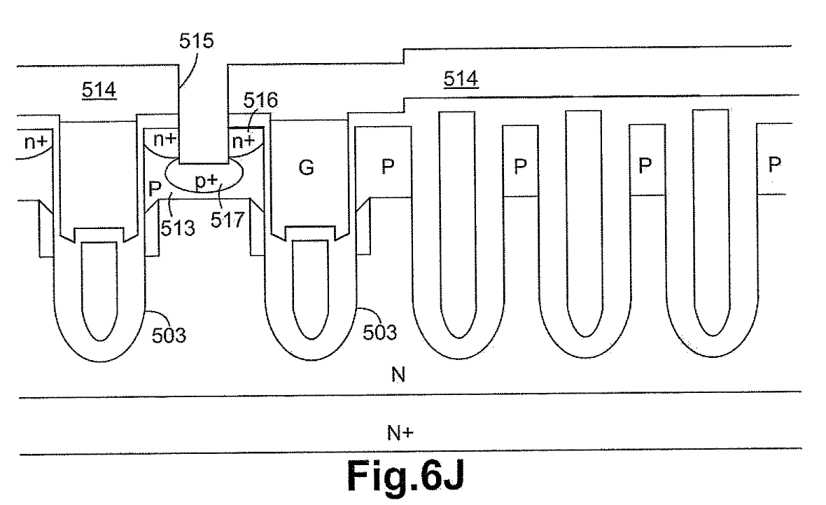

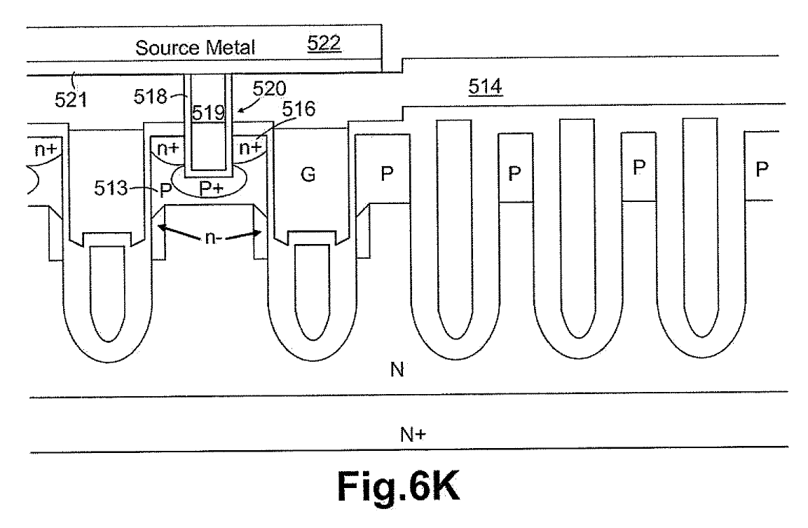

FIGS. 6A to 6K are a series of exemplary steps that are performed to form the inventive N-channel trench MOSFET 500 in FIG. 5. In FIG. 6A, an N epitaxial layer 501 is grown on an N+ substrate 502. Then, after a trench mask (not shown) is applied onto the N epitaxial layer 501, a plurality of active trenches 503 and multiple termination trenches 504 are etched respectively in an active area and in a termination area by dry silicon etch. Next, a sacrificial oxide (not shown) is first grown and then removed to eliminate the plasma damage introduced during opening all kinds of the trenches. After that, a field oxide 505 is formed covering a top surface of the N epitaxial layer 501 and along inner surfaces of all the active trenches 503 and the termination trenches 504. Then, a p type (or n type) poly-silicon layer 506 is formed onto the field oxide 505 and is then patterned by poly CMP (Chemical Mechanical Polishing) or etching back to leave necessary portion into the termination trenches 504 to from multiple trenched floating gates 531.

In FIG. 6B, after applying a shielded electrode mask, the p type poly-silicon layer 506 in the active area defined by the shielded electrode mask is etched back to leave necessary portion in a lower portion of each of the active trenches 503 to serve as a shielded electrode 506′. Next, the field oxide 505 is accordingly etched back from an upper portion of each of the active trenches 503 to expose a top surface of the shielded electrode 506′.

In FIG. 6C, after the shielded electrode mask is removed, another oxide layer is formed: covering the top surface of the shielded electrode 506′ and the field oxide 505 to serve as an inter-poly insulating layer 507; and along upper sidewalls of the active trenches 503 to serve as a gate oxide 508. Next, a step of Boron or BF2 angle ion implantations is carried out to form n− avalanche enhancement regions 509 in the N epitaxial layer 501 along the upper sidewalls of each of the active trenches 503.

In FIG. 6D, an un-doped or doped poly-silicon layer 510 is deposited covering the gate oxide 508 and the inter-poly insulating layer 507.

In FIG. 6E, a layer of nitride is deposited covering the un-doped or doped poly-silicon layer 510, and is then patterned by anisotropic nitride etch to form nitride sidewall spacers 511 along the upper sidewalls of the active trenches 503.

In FIG. 6F, a thermal oxidation is performed to form a thick oxide on the top surface of the shielded electrode 506′, therefore the inter-poly insulating layer 507 is thicker than the gate oxide 508 which is prevented from the thermal oxidation by the nitride sidewall spacers 511 as shown in FIG. 6E. Next, the nitride sidewall spacers are removed away.

In FIG. 6G, an n+doped poly-silicon layer is deposited and then is etched back to leave necessary portion in upper portions of the active trenches 503, which is merged together with the un-doped or doped poly-silicon layer 510 as shown in FIG. 6E to form a gate electrode 512 in the upper portion of each of the active trenches 503.

In FIG. 6H, a body ion implantation is carried out without requiring a body mask, and then followed by a body diffusion to form a plurality of P body regions 513 in an upper portion of the N epitaxial layer 501, therefore, the n− avalanche enhancement regions 509 are made located below the P body regions 513.

In FIG. 6I, a contact interlayer 514 is deposited covering entire top surface of FIG. 6H, and then, after applying a contact mask (not shown), a dry oxide etch is performed to etch a contact hole 515 penetrating through the contact interlayer 514 and expose a top surface of the P body region 513 between two adjacent active trenches 503. Next, a step of Arsenic or Phosphorus ion implantation is carried out through the contact hole 515, and followed by a source diffusion to form an n+source region 516 in upper portion of the P body region 513 and having a greater junction depth and a higher doping concentration in the middle portion of two adjacent active trenches 503.

In FIG. 6J, a dry silicon etch is performed to further etch the contact hole 515 to penetrate through the n+ source region 516 and extend into the P body region 513. Then, a BF2 ion implantation is carried out to form a p+ body ohmic doped region 517 underneath the n+source region 516 and surrounding at least bottom of the contact hole 515.

In FIG. 6K, a barrier metal layer 518 of Ti/TiN (or Co/TiN or Ta/TiN) is deposited overlying the contact interlayer 514 and along inner surface of the contact hole 515 (as illustrated in FIG. 6J), then, a step of RTA (Rapid thermal Annealing) is optionally performed to form Ti silicide. Next, tungsten material is deposited onto the barrier metal layer and followed by tungsten etch back and Ti/TiN etch back to form a tungsten plug 519 to serve as a contact metal plug for a trenched source-body contact 520. After that, a resistance-reduction layer 521 of Ti or Ti/TiN and a metal layer 522 of Al alloys or Ni/Ag are successively deposited overlying the contact interlayer 514 and covering top of the trenched source-body contact 520, which are then patterned by a source mask (not shown) to form a source metal shorted to the n+ source region 516 and the P body region 513 through the trenched source-body contact 520.

Although the present invention has been described in terms of the presently preferred embodiments, it is to be understood that such disclosure is not to be interpreted as limiting. Various alternations and modifications will no doubt become apparent to those skilled in the art reading the above disclosure. Accordingly, it is intended that the appended claims be interpreted as covering all alternations and modifications as fall within the true spirit and scope of the invention.

What is claimed is:

1. A trench MOSFET, comprising:
a substrate of a first conductivity type;
an epitaxial layer of said first conductivity type onto said substrate, said epitaxial layer having a lower doping concentration than said substrate;
a plurality of active trenches formed in said epitaxial layer in an active area, each comprising a shielded electrode in a lower portion and a gate electrode in an upper portion, wherein said shielded electrode is insulated from said epitaxial layer by a field oxide and said gate electrode is insulated from source regions of said first conductivity type and body regions of a second conductivity type by a gate oxide, wherein said shielded electrode and said gate electrode are insulated from each other by an inter-poly insulating layer; and
avalanche enhancement regions of said first conductivity type formed adjacent sidewalls of each of said active trenches below said body regions and towards a bottom of each of said active trenches, wherein said avalanche enhancement regions having a lower doping concentration than said epitaxial layer.

2. The trench MOSFET of claim 1, wherein said avalanche enhancement regions further extend below said gate oxide but above a bottom of said shielded electrode.

3. The trench MOSFET of claim 1, wherein said avalanche enhancement regions further extend surrounding the bottom of each of said active trenches.

4. The trench MOSFET of claim 1 further comprising trenched source-body contacts filled with a contact metal plug, penetrating through a contact interlayer overlying said epitaxial layer and said source regions; and further extending into said body regions.

5. The trench MOSFET of claim 4, wherein each of said source regions having a greater junction depth and a higher doping concentration along sidewalls of said trenched source-body contacts than along an adjacent channel region near said active trenches at a same distance from a top surface of said epitaxial layer.

6. The trench MOSFET of claim 4, wherein each of said source regions having a same junction depth and a same doping concentration from sidewalls of said trenched source-body contact to an adjacent channel region near said active trenches at a same distance from a top surface of said epitaxial layer.

7. The trench MOSFET of claim 1, wherein said inter-poly insulating layer has a same thickness as said gate oxide.

8. The trench MOSFET of claim 1, wherein said inter-poly insulating layer has a greater thickness than said gate oxide.

9. The trench MOSFET of claim 4, wherein said contact metal plug is Al alloys or Ni/Ag padded by a barrier metal layer of Ti/TiN, which is further out extending to overlying said contact interlayer to act as a source metal.

10. The trench MOSFET of claim 4, wherein said contact metal plug is tungsten plug padded by a barrier metal layer of Ti/TiN or Co/TiN or Ta/TiN, and is connected to a source metal.

11. The trench MOSFET of claim 10, wherein said contact metal plug is also extending over a top surface of said contact interlayer.

12. The trench MOSFET of claim 10, wherein said source metal is Al alloys or Ni/Ag padded by a resistance-reduction layer of Ti or Ti/TiN.

13. The trench MOSFET of claim 10, wherein said source metal is Al alloys or Ni/Ag and not padded by a resistance-reduction layer.

14. The trench MOSFET of claim 1 further comprising multiple trenched floating gates in a termination area.

15. The trench MOSFET of claim 1 wherein said field oxide is thicker than said gate oxide.

16. A method of making a trench MOSFET with shielded electrode, comprising:
forming a plurality of active trenches in an epitaxial layer of a first conductivity type supported onto a substrate of said first conductivity type;
forming a shielded electrode padded by a field oxide in a lower portion of each of said active trenches;
carrying out angle ion implantations to form avalanche enhancement regions of said first conductivity type in said epitaxial layer along upper sidewalls of each of said active trenches before forming a gate electrode in an upper portion of each of said active trenches, wherein said avalanche enhancement regions having a lower doping concentration than said epitaxial layer.

17. The method of claim 16, after forming said avalanche enhancement region, further comprising:
depositing an un-doped or doped poly-silicon layer overlying a gate oxide along upper sidewalls of each of said active trenches;
depositing a nitride layer overlying said un-doped or doped poly-silicon layer;
carrying out anisotropic nitride etch to form nitride sidewalls spacers along the upper sidewalls of each of said active trenches;
performing thermal oxidation to form a thick oxide as an inter-poly insulating layer on top surface of said shielded electrode, which has a greater thickness than said gate oxide.

18. The method of claim 16, further comprising:
forming a gate electrode of said first conductivity type above said shielded electrode and adjacent to a gate oxide in an upper portion of each of said active trenches;
carrying out body ion implantation of a second conductivity type dopant and body diffusion to form body regions surrounding said gate electrode;
depositing a contact interlayer covering entire top surface and applying a contact mask whereon;
etching a plurality of contact holes defined by said contact mask through said contact interlayer to expose a top surface of said body regions;
performing ion implantation of said first conductivity type dopant through said contact holes and performing a source diffusion to form source regions.

19. The method claim 16, wherein said shielded electrode is of said first conductivity type or a second conductivity
